(19) United States
(12) Patent Application Publication
(10) Pub. No.: US 2026/0068309 A1
(43) Pub. Date: Mar. 5, 2026

(54) SEMICONDUCTOR DEVICE AND METHOD OF FABRICATING THE SAME

(71) Applicant: UNITED MICROELECTRONICS CORP., Hsin-Chu City (TW)

(72) Inventor: Po-Yu Yang, Hsinchu City (TW)

(73) Assignee: UNITED MICROELECTRONICS CORP., Hsin-Chu City (TW)

(21) Appl. No.: 18/909,956

(22) Filed: Oct. 9, 2024

(30) Foreign Application Priority Data
Aug. 29, 2024 (TW) 113132478

(51) Int. Cl. H01L 27/092; H01L 21/8238; H01L 29/06; H01L 29/10; H01L 29/15; H01L 29/423; H01L 29/66; H01L 29/775; H01L 29/78; H01L 29/786

(52) U.S. Cl. CPC H10D 84/856; H10D 30/014; H10D 30/024; H10D 30/43; H10D 30/6211; H10D 30/6735; H10D 30/6757; H10D 30/751; H10D 62/121; H10D 62/8164; H10D 64/017; H10D 84/0167; H10D 84/0193; H10D 84/038; H10D 84/853

(57) ABSTRACT

A semiconductor device includes a substrate, a first transistor and a second transistor. The first transistor is disposed on the substrate and includes two first source/drain structures; a plurality of channel layers separately disposed on the substrate and disposed between the two first source/drain structures; and a first gate structure surrounding the channel layers. The second transistor is disposed on the substrate and includes two second source/drain structures; a superlattice channel layer disposed on the substrate and disposed between the two second source/drain structures, wherein the superlattice channel layer comprises a plurality of first superlattice layers and a plurality of second superlattice layers, which are alternately stacked on the substrate; and a second gate structure disposed above the superlattice channel layer.

### BACKGROUND OF THE INVENTION

### 1. Field of the Invention

The invention relates to the field of semiconductor devices and a method of fabricating the same, and more particularly to a semiconductor device having combined a gate-all-around (GAA) transistor and a fin field effect transistor (FinFET), and a method of fabricating the same.

### 2. Description of the Prior Art

When semiconductor devices were developed to 65 nm technology generation, it was difficult to further scale down by using conventional planar metal-oxide-semiconductor (MOS) transistor processes. Therefore, non-planar multi-gates transistor devices, e.g., dual-gates FinFETs, tri-gates FinFETs and omega FinFETs, were developed in prior art to replace the planar transistor devices. Nowadays, the semiconductor devices have been developed down to 2 nm or less. GAA transistor devices using a nanowire structure or a nanosheet as a channel function as a solution to further enhance device integration and device performance. However, in certain semiconductor devices, GAA transistors cannot replace the FinFETs while effectively improving electron mobility. Thus, it would result in application difficulties and manufacturing process complexity. Therefore, currently available technologies need to be further improved to effectively enhance device properties of semiconductor devices for application in specific devices.

### SUMMARY OF THE INVENTION

An object of the present invention is to provide a semiconductor device, in which gate structures are respectively arranged on a channel layer and a superlattice channel layer to form an N-type gate-all-around (GAA) transistor and a P-type fin field effect transistor (FinFET). In this way, the P-type fin field effect transistor can effectively improve the electron mobility while reducing configuration area thereof. Accordingly, the semiconductor device including both the P-type FinFET and the N-type GAA transistor can be applied to specific devices (such as inverters, static random access memories, etc.) to achieve excellent operational performance and device efficacy.

Another object of the present invention is to provide a method of fabricating a semiconductor device, which integrates the formation of a GAA transistor and a FinFET. Gate structures are formed on a channel layer and a superlattice channel layer, respectively, to form an N-type GAA transistor and a P-type FinFET. According to the method of the invention, the P-type FinFET can be formed with effectively improved electron mobility while reducing the configuration area. In this way, the semiconductor device according to the present invention can be applied to specific devices (such as inverters, static random access memories, etc.) and achieve excellent operational performance and device performance.

In order to achieve the above and further objects, a semiconductor device is provided according to the present invention. The semiconductor device includes a substrate, a first transistor and a second transistor. The first transistor is disposed on the substrate and includes two first source/drain structures; a plurality of channel layers separately disposed on the substrate and disposed between the two first source/drain structures; and a first gate structure surrounding the channel layers. The second transistor is disposed on the substrate and includes two second source/drain structures; a superlattice channel layer disposed on the substrate and disposed between the two second source/drain structures, wherein the superlattice channel layer comprises a plurality of first superlattice layers and a plurality of second superlattice layers, which are alternately stacked on the substrate; and a second gate structure disposed above the superlattice channel layer.

In order to achieve the above and further objects, a method of fabricating a semiconductor device is also provided according to the present invention. The method of fabricating a semiconductor device includes: providing a substrate; forming a first transistor on the substrate; and forming a second transistor on the substrate. The first transistor is formed on the substrate and includes two first source/drain structures; a plurality of channel layers separately formed on the substrate between the two first source/drain structures; and a first gate structure surrounding the channel layers. The second transistor is formed on the substrate and includes two second source/drain structures; a superlattice channel layer formed on the substrate and between the two second source/drain structures, wherein the superlattice channel layer comprises a plurality of first superlattice layers and a plurality of second superlattice layers, which are alternately stacked on the substrate; and a second gate structure formed above the superlattice channel layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a semiconductor device according to a preferred embodiment of the present invention;

FIG. 2 is a schematic diagram illustrating an equivalent circuit of a semiconductor device according to a preferred embodiment of the present invention;

FIG. 3 is a schematic diagram illustrating another equivalent circuit of a semiconductor device according to a preferred embodiment of the present invention;

FIG. 4 to FIG. 10 are schematic diagrams illustrating a method of fabricating a semiconductor device according to a preferred embodiment of the present invention, wherein:

FIG. 4 is a cross-sectional view schematically illustrating an intermediate of the semiconductor device after a superlattice material layer is formed;

FIG. 5 is a cross-sectional view schematically illustrating an intermediate of the semiconductor device after a dummy gate structure is formed;

FIG. 6 is a cross-sectional view schematically illustrating an intermediate of the semiconductor device after a lateral etching process is performed;

FIG. 7 is a cross-sectional view schematically illustrating an intermediate of the semiconductor device after source/drain structures are formed;

FIG. 8 is a cross-sectional view schematically illustrating an intermediate of the semiconductor device after a replacement process of metal gate is performed;

FIG. 9 is a cross-sectional view schematically illustrating an intermediate of the semiconductor device after a selective etching process is performed; and

FIG. 10 is a cross-sectional view schematically illustrating an intermediate of the semiconductor device after a transistor is formed.

### DETAILED DESCRIPTION

To provide a better understanding of the present invention, preferred embodiments will be described in detail. The preferred embodiments of the present invention are illustrated in the accompanying drawings with numbered elements. In addition, the technical features in different embodiments described in the following may be replaced, recombined, or mixed with one another to constitute another embodiment without departing from the spirit of the present invention.

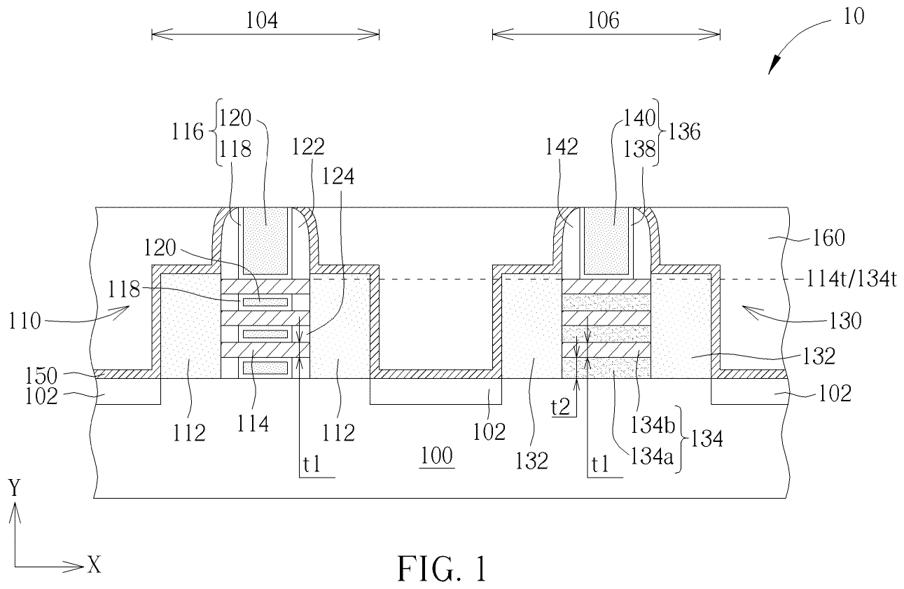

Please refer to FIG. 1, which is a cross-sectional diagram schematically illustrating a semiconductor device 10 according to an embodiment of the invention. The semiconductor device 10 includes a substrate 100, a first transistor 110 and a second transistor 130. The substrate 100 may include, for example, a silicon substrate, a silicon-containing substrate such as silicon carbide or silicon germanium, or a silicon-on-insulator substrate, and at least one shallow trench isolation 102 is arranged in the substrate 100 to define at least two active areas, e.g., a first region 104 and a second region 106, in the substrate 100. In an embodiment, the first region 104 and the second region 106 are arranged adjacent to each other in a horizontal direction X, for example, in a manner as shown in FIG. 1, but not limited thereto.

The first transistor 110 and the second transistor 130 are both disposed on the substrate 100 and located in the first region 104 and the second region 106, respectively. In detail, the first transistor 110 further includes two first source/drain structures 112, a plurality of channel layers 114 and a first gate structure 116, which are separated from each other. The channel layers 114 are disposed above the substrate 100 at intervals along a vertical direction Y, without contact with the substrate 100. The channel layers 114 are disposed between the two first source/drain structures 112, while the first gate structure 116 is disposed on the substrate 100 and surrounds each channel layer 114, so that the first transistor 110 can be used as a gate-all-around (GAA). On the other hand, the second transistor 130 includes two second source/drain structures 132, a superlattice channel layer 134 and a second gate structure 136, which are separately disposed from each other. The superlattice channel layer 134 is disposed on the substrate 100, in direct contact with the substrate 100. The superlattice channel layer 134 is disposed between the two second source/drain structures 132, and the second gate structure 136 is disposed on the superlattice channel layer 134, so that the second transistor 130 can be used as a fin field effect transistor (FinFET).

In particular, the superlattice channel layer 134 includes a plurality of first superlattice layers 134a and a plurality of second superlattice layers 134b, which are alternately stacked. In an embodiment, the first superlattice layers 134a and the second superlattice layers 134b include different epitaxial materials. For example, the first superlattice layers 134a include epitaxial silicon germanium (SiGe) and the second superlattice layers 134b include epitaxial silicon (Si), but not limited thereto. Since the first superlattice layers 134a and the second superlattice layers 134b included in the superlattice channel layer 134 are sequentially arranged by stacking one second superlattice layer 134b on one first superlattice layer 134a and stacking another first superlattice layer 134a on the second superlattice layer 134b, an effect of enhancing electron-flow performance can be achieved due to the lattice structures thereof. As such, by disposing the second gate structure 136 on the superlattice channel layer 134, electron mobility of the second transistor 130 can be effectively improved without increasing configuration area or channel width of the second gate structure 136, and the second transistor 130 can achieve better device efficacy and operational performance. Under this arrangement, the semiconductor device 10 in this embodiment can be advantageously applied to a specific device, such as an inverter or a static random access memory (SRAM).

Refer to FIG. 1 again. The topmost surface 114t of the channel layer 114 disposed in the first region 104 is preferably on the same plane as the topmost surface 134t of the superlattice channel layer 134 disposed in the second region 106. In detail, each second superlattice layer 134b and each first superlattice layer 134a arranged in the second region 106 have the same thickness t1 and t2, respectively, while each channel layer 114 arranged in the first region 104 also has the same thickness t1. The thickness t1 and the thickness t2 are about 5 to 15 nanometers, for example, but are not limited thereto. In an embodiment, the thickness t1 of each second superlattice layer 134b is, for example, equal to the thickness t2 of each first superlattice layer 134a, and the thickness t1 and material of each second superlattice layer 134b can also be selectively identical to the thickness t1 and material of the channel layer 114. Therefore, the second superlattice layer 134b disposed in the second region 106 and the channel layer 114 disposed in the first region 104 can be formed in the same process.

The first transistor 110 further includes a first top spacer 122 and a first bottom spacer 124 disposed around the upper-half portion and the lower-half portion of the first gate structure 116, respectively. The first top spacer 122 is disposed above the channel layer 114. The first bottom spacer 124 is disposed below the first top spacer 122 and sandwiched between adjacent two channel layers 114 or between one channel layer 114 and the substrate 100 in the vertical direction Y. Therefore, sidewalls of the first bottom spacer 124 are aligned with sidewalls of the first top spacer 122 and the channel layer 114. On the other hand, in the horizontal direction X, the first bottom spacer 124 is disposed between the first gate structure 116 and each of the first source/drain structures 112 to electrically isolate the first gate structure 116 from each of the first source/drain structures 112. In addition, the first gate structure 116 further includes a first gate dielectric layer 118 and a first gate layer 120 sequentially arranged around each channel layer 114, so that the first gate dielectric layer 118 is disposed between one channel layer 114 and the first gate layer 120. In one embodiment, the first gate dielectric layer 118 includes a dielectric material with a high dielectric constant, and the first gate layer 120 includes a metal material with a low resistance, such as, but not limited to, aluminum, tungsten or titanium.

The second transistor 130 further includes a second spacer 142 disposed around the second gate structure 136. The second gate structure 136 includes a second gate dielectric layer 138 and a second gate layer 140 sequentially disposed above the superlattice channel layer 134. In one embodiment, the second gate dielectric layer 138 includes a dielectric material with a high dielectric constant, and the second gate layer 140 includes a metal material with a low resistance, such as, but not limited to, aluminum, tungsten or titanium. In another embodiment, the first top spacer 122 and the first bottom spacer 124 of the first gate structure 116, and the second spacer 142 of the second gate structure 136 respectively include an insulating material, such as silicon oxide, silicon nitride, silicon carbon nitride or the like. The material of the first top spacer 122 of the first gate structure 116 is preferably the same as that of the second spacer 142 of the second gate structure 136. The first top sidewall spacer 122 disposed in the first region 104 and the second sidewall spacer 142 disposed in the second region 106 can also be formed in the same process, but not limited thereto.

In addition, the semiconductor device 10 further includes a contact etching stop layer (CESL) 150 and an interlayer dielectric layer (ILD) 160 sequentially disposed on the substrate 100 to simultaneously cover the first transistor 110 disposed in the first region 104 and the second transistor 130 disposed in the second region 106. In one embodiment, the contact etch stop layer 150 and the interlayer dielectric layer 160 respectively include an insulating material, such as silicon oxide, silicon nitride, silicon carbonitride, etc., and the material of the contact etch stop layer 150 is preferably different from that of the interlayer dielectric layer 160, but not limited thereto. It should be noted that the first source/drain structures 112 of the first transistor 110 and the second source/drain structures 132 of the second transistor 130 respectively include different epitaxial materials (such as epitaxial silicon germanium, epitaxial carbon silicide or epitaxial phosphorus silicide, etc.) and different dopants (n-type dopants or p-type dopants), so that the first transistor 110 and the second transistor 130 include different conductivity types. In a preferred embodiment, the first source/drain structures 112 include, for example, epitaxial carbon silicide and N-type dopants, so that the first transistor 110 includes an N-type MOS transistor semiconductor. On the other hand, the second source/drain structures 132 includes, for example, epitaxial silicon germanium and P-type dopants, so that the second transistor 130 includes, but is not limited to, a P-type MOS transistor semiconductor.

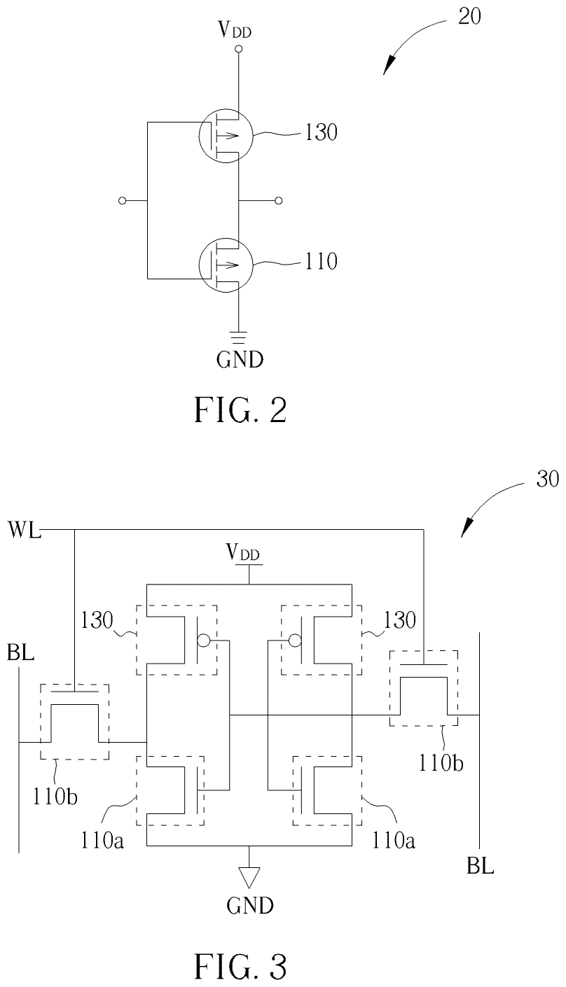

Under this arrangement, the formation of the P-type FinFET (i.e. the second transistor 130) of the semiconductor device 10 can be partially integrated with the process of forming the N-type GAA transistor (i.e. the first transistor 110). Moreover, the electron mobility of the P-type fin field effect transistor can be effectively improved on the premise of avoiding enlargement of the configuration area or channel width of the gate structure. For example, the electron flow amount can be increased by about 52% compared with a P-type GAA transistor, but it is not limited thereto. Therefore, the semiconductor device 10 in this embodiment can be advantageously applied to devices including both N-type transistor and P-type transistor, such as an inverter device 20 as shown in FIG. 2 or a SRAM device 30 as shown in FIG. 3. With the P-type FinFET and the N-type GAA transistor of the semiconductor device 10, the operational performance and device efficacy of the inverter device 20 and the SRAM device 30 can be improved as a whole.

In detail, in an embodiment as illustrated in FIG. 2, the inverter device 20 includes a second transistor 130 and a first transistor 110, wherein the source/drain structures of the second transistor 130 and the first transistor 110 (not shown in FIG. 2) include, for example, P-type dopants and N-type dopants, respectively, to serve as a P-type FinFET and an N-type GAA transistor. Under this arrangement, the second transistor 130 and the first transistor 110 can be configured as a pull-up transistor and a pull-down transistor connected to a high voltage source VDD and a ground GND, respectively. With the arrangement of the first transistor 110 and the second transistor 130, the inverter device 20 in this embodiment can achieve good operational performance and device efficacy on the premise of avoiding enlargement of device area.

In another embodiment as illustrated in FIG. 3, the SRAM device 30 includes two second transistors 130 and four first transistors 110a and 110b. The first transistors 110a and 110b include, for example, N-type dopants and P-type dopants to serve as an N-type GAA transistor and a P-type GAA transistor, respectively, while the second transistor 130 include P-type dopants to serve as a P-type FinFET. Under this arrangement, the SRAM device 30 in this embodiment can be used in a six-transistor SRAM (6T-SRAM), in which the two first transistors 110a (N-type GAA transistors) and two first transistors 110b (P-type GAA transistors), in lieu of common transistors, can be configured as pull-up transistors and pull-down transistors, respectively, to form a flip-flop. In this way, two terminals of the flip-flop are electrically connected to a high voltage source VDD and a ground GND, respectively, and a latch is formed between the first transistors 110a and 110b to store data in a storage node, SN (not shown in the drawings). On the other hand, the second transistor 130 (P-type FinFET) with small configuration area and high electron mobility can be used in lieu of an N-type transistor in a general SRAM device to function as an access transistor. Accordingly, the gate (not shown in FIG. 3) and the source (not shown in FIG. 3) of each second transistor 130 are respectively coupled to the corresponding signal lines WL and BL for receiving or transmitting data. With the arrangement of the first transistors 110a and 110b and the second transistors 130, the SRAM device 30 in this embodiment can effectively achieve good operational performance and device efficacy on the premise of avoiding enlargement of device area.

It is understood by those skilled in the art that the semiconductor device according to the invention may have alternative configurations, which are not limited to the above embodiments, as long as requirements for actual products can be met. For example, in an embodiment, the thickness t2 of the first superlattice layer 134a of the superlattice channel layer 134 may also be greater than the thickness t1 of the second superlattice layer 134b. In a more specific embodiment, a ratio of the thickness t1 to the thickness t2 may be about 1/0.75˜1/3. For example, when the thickness t2 of the first superlattice layer 134a is about 2 to 8 nanometers, the thickness t1 of the second superlattice layer 134b can be about 6 to 12 nanometers, but is not limited thereto. Accordingly, the electron mobility of the second transistor 130 can be further improved, and better operational performance and device efficacy can be achieved in the application of, for example, the inverter device 20 or the SRAM device 30.

In order to make the semiconductor device 10 according to the invention readily understood by those who are familiar with the technical field to which the invention belongs, a method of forming the semiconductor device 10 according to the invention will be further described below.

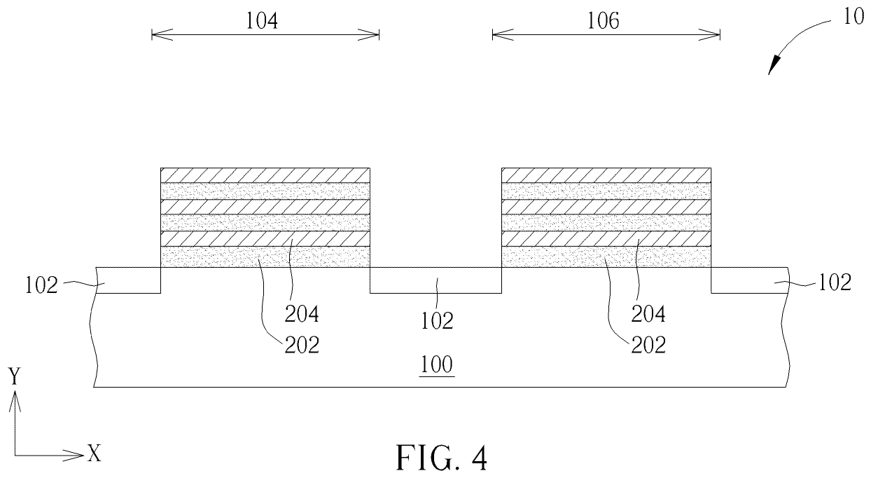

Please refer to FIG. 4 to FIG. 10, which are schematic diagrams illustrating a method of fabricating the semiconductor device 10 according to a preferred embodiment of the present invention. First, as shown in FIG. 4, a substrate 100 is provided, and shallow trench isolations 102 are formed in the substrate 100. Meanwhile, a first region 104 and a second region 106, which are electrically insulated from each other by the shallow trench isolation 102, are defined on the substrate 100. Next, an epitaxial growth process is performed to form a stack of at least one first superlattice material layer 202 and at least one second superlattice material layer 204 on the substrate 100 in both the first region 104 and the second region 106, so as to form a stack structure in both the first region 104 and the second region 106. It should be understood by those skilled in the art that a number of layers included in the stack of the first superlattice material layer 202 and the second super superlattice material layers 204 can be varied according to the actual process requirements, and it is not limited to four first superlattice material layers 202 and four second superlattice material layers 204 as shown in FIG. 4. In an embodiment, the first superlattice material layers 202 and the second superlattice material layers 204 include different epitaxial materials, and can be selected from, for example, epitaxial silicon germanium, epitaxial germanium or epitaxial silicon, etc.. Preferably, the first superlattice material layers 202 include epitaxial silicon germanium, and the second superlattice material layers 204 include epitaxial silicon, but it is not limited thereto.

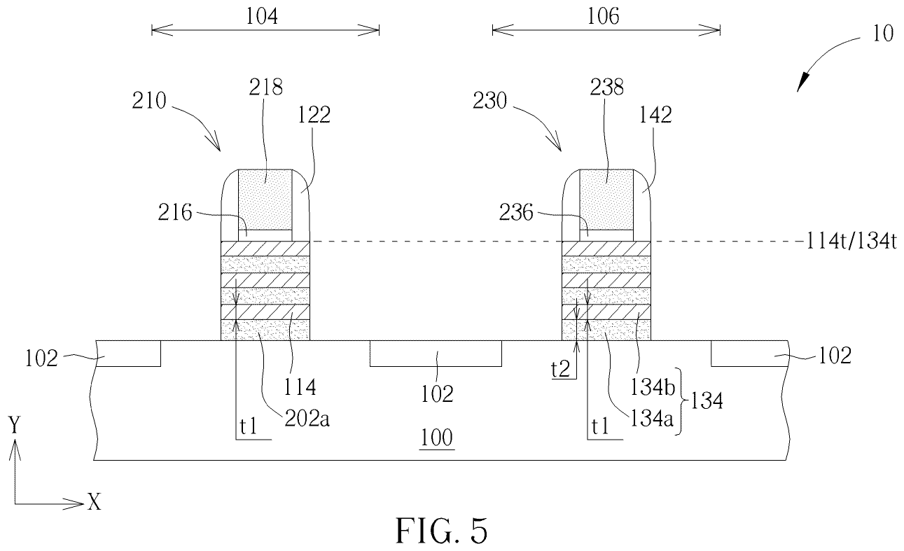

As shown in FIG. 5, a first dummy gate structure 210 and a second dummy gate structure 230 are formed on the stack structures in the first region and the second region, respectively. Subsequently, a first top spacer 122 and a second spacer 142 surrounding the first dummy gate structure 210 and the second dummy gate structure 230 are formed on the stack structure in the first region 104 and the second region 106, respectively. In detail, the processes of forming the first dummy gate structure 210 and the second dummy gate structure 230 include, but are not limited to, the following steps. First, a chemical/physical vapor deposition (CVD/PVD) process is performed to sequentially form a gate dielectric material layer (not shown in the drawings) and a gate material layer (not shown in the drawings) on the stack structure in the first region 104 and the second region 106. Then the gate dielectric material layer and the gate material layer are partially removed through a patterning process, thereby forming a stack structure of a gate dielectric layer 216 and a gate layer 218 in the first region 104. The stack structure of the gate dielectric layer 216 and the gate layer 218 forms the first dummy gate structure 210. On the other hand, a gate dielectric layer 236 and a gate layer 238 are sequentially formed to provide another stack structure in the second region 106, so as to form the second dummy gate structure 230.

Then, the first dummy gate structure 210 and the first top spacer 122 are used as an etching mask to pattern the stack under the first dummy gate structure 210 and the first top spacer 122 into a stack structure of alternately arranged first superlattice material layers 202a and channel layers 114. Meanwhile, the second dummy gate structure 230 and the second spacer 142 are used as an etching mask to pattern the stack under the second dummy gate structure 230 and the second sidewall spacer 142 into a superlattice channel layer 134, which includes a stack structure of alternately arranged first superlattice layers 134a and second superlattice layers 134b. Accordingly, sidewalls of the first superlattice material layers 202a and the channel layers 114 are aligned with the first top spacer 122 in the vertical direction Y, and the substrate 100 disposed at both sides thereof are exposed. Likewise, sidewalls of the superlattice channel layer 134 are aligned with the second spacer 142 in the vertical direction Y, and the substrates 100 at both sides thereof are also exposed, as shown in FIG. 5.

It should be noted that since the channel layers 114 in the first region 104 and the superlattice channel layer 134 in the second region 106 are formed simultaneously through the same process, the topmost surface 114t of the channel layers 114 and the topmost surface 134t of the superlattice channel layer 134 are located on the same plane. In addition, since the channel layers 114 and the second superlattice layers 134b in each superlattice channel layer 134 are both formed by patterning the second superlattice material layer 204, the channel layer 114 and the second superlattice layer 134b can have the same thickness t1 and made of the same material. In a preferred embodiment, the thickness t1 of the second superlattice layer 134b can also be selectively equal to or less than the thickness t2 of the first superlattice layer 134a in the same superlattice channel layer 134, but it is not limited thereto.

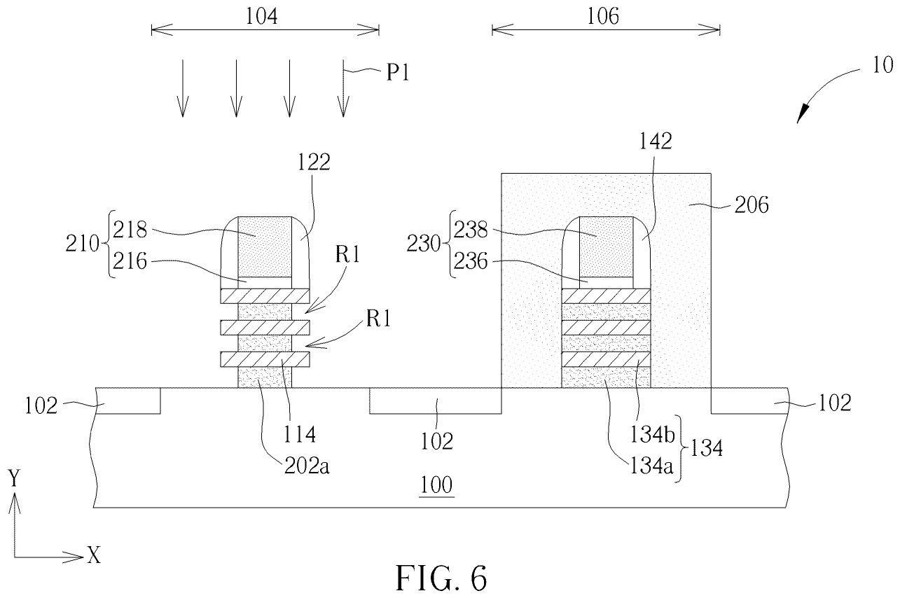

As shown in FIG. 6, a mask layer 206 is formed in the second region 106, covering the second dummy gate structure 230, the second spacer 142 and the superlattice channel layer 134 underneath. Then, with the covering of the mask layer 206, a lateral etching process P1 is performed on the first superlattice material layers 202a in the first region 104, thereby removing a part of the first superlattice material layer 202a from both sides of each first superlattice material layer 202a, so as to form a plurality of grooves R1. As such, each of the grooves R1 is formed between two adjacent channel layers 114, or between one channel layer 114 and the substrate 100. Furthermore, the grooves R1 are formed right below the first top spacer 122 in the vertical direction Y.

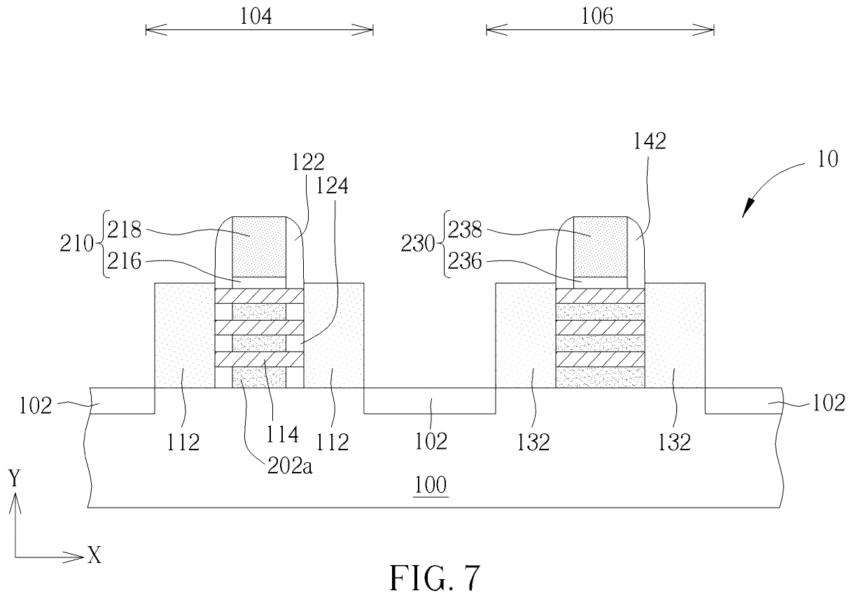

As shown in FIG. 7, a deposition process and a dry etching process are sequentially performed in the first region 104 to form a first bottom spacer 124 filling the grooves R1. In detail, the first bottom spacer 124 is formed right below the first top spacer 122 and disposed between two adjacent channel layers 114 or between one channel layer 114 and the substrate 100 in the vertical direction Y. In a preferred embodiment, sidewalls of the first bottom spacer 124 are, for example, aligned with sidewalls of the first top spacer 122, but it is not limited thereto.

Subsequently, as shown in FIG. 7, an epitaxial growth process is performed to form an epitaxial layer on the exposed substrate 100 in the first region 104 as the first source/drain structures 112. Then, after the mask layer 206 is completely removed, another epitaxial growth process is performed to form another epitaxial layer on the exposed substrate 100 in the second region 106 as the second source/drain structures 132. The first source/drain structures 112 and the second source/drain structures 132 of the second transistor 130 include different epitaxial materials, which may be selected from, for example, epitaxial silicon germanium, epitaxial carbon silicide or epitaxial phosphorus silicide, etc., and include different dopants (n-type dopants or p-type dopants). However, it is not limited thereto. In an embodiment, when the epitaxial growth process is performed, an in-situ doping process may be simultaneously performed. That is, when the epitaxial layers are formed, appropriate N-type dopants or P-type dopants are also implanted. However, it is not limited thereto.

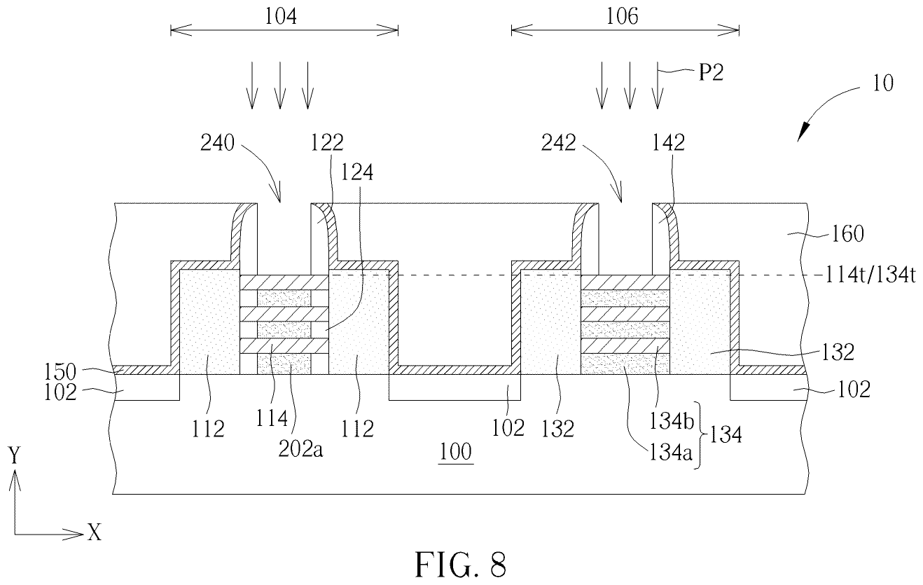

As shown in FIG. 8, a contact etch stop layer (CESL) 150 and an interlayer dielectric layer (ILD) 160 are sequentially formed on the substrate 100 to cover the first dummy gate structure 210 in the first region 104 and the second dummy gate structure 230 in the second region 106. In detail, the formation of the CESL 150 and the ILD 160 includes, but is not limited to, the following steps. First, a contact etch stop material layer (not shown in the drawings) and a dielectric material layer (not shown in the drawings) are sequentially formed on the substrate 100 in a manner that the contact etch stop material layer conformally covers the first dummy gate structure 210 in the first region 104 and the second dummy gate structure 230 in the second region 106. Then the dielectric material layer overlies the contact etch stop material layer as a whole. The dielectric material layer and the contact etch stop material layer are then partially removed by executing a planarizing process, thereby forming the CESL 150 and the ILD 160, and the top surfaces of the first dummy gate structure 210 and the second dummy gate structure 230 are exposed.

Subsequently, as shown in FIG. 8, a replacement process of metal gate P2 is performed to completely remove the gate dielectric layer 216 and the gate layer 218 located in the first region 104 and the gate dielectric layer 236 and the gate layer 238 located in the second region 106, thereby simultaneously forming the first gate trench 240 in the first region 104 and the second gate trench 242 in the second region 106.

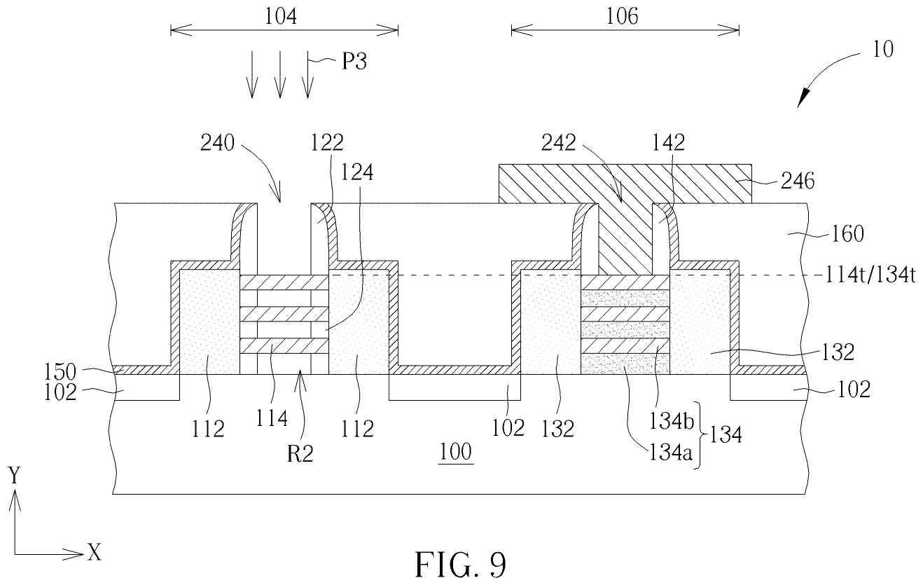

As shown in FIG. 9, a mask layer 246 is formed in the second region 106 to fill the second gate trench 242 and further overlie the ILD 160. Then, a selective etching process P3 is performed with the covering of the mask layer 246 to etch the remaining first superlattice material layer 202a downward from the first gate trench 240, thereby forming a plurality of gaps R2, each of which is disposed between two adjacent channel layers 114 or between one channel layer 114 and the substrate 100.

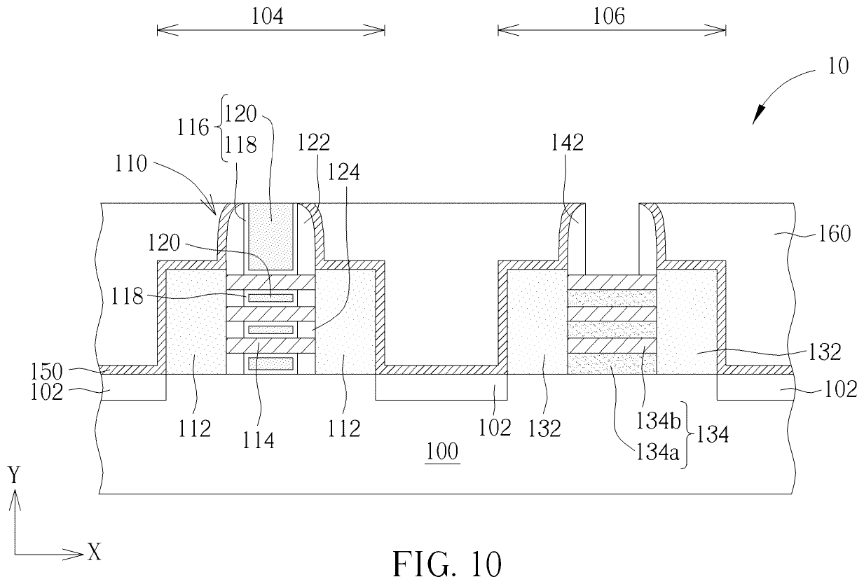

As shown in FIG. 10, first gate dielectric layers 118 and first gate layers 120 filling the first gate trench 240 and the gaps R2 are sequentially formed in the first region 104. In this way, one of the first gate dielectric layers 118 and one of the first gate layers 120 together form the first gate structure 116, and the first gate structure 116 surrounds the channel layers 114 as a whole. Accordingly, a gate-all-around effect can be achieved. In an embodiment, the first gate dielectric layer 118 includes a dielectric material with a high dielectric constant, and the first gate layer 120 includes a metal material with a low resistance, for example, but not limited to, aluminum, tungsten or titanium. Moreover, in another embodiment, a work function metal layer (not shown in the drawings) and at least one barrier layer (not shown in the drawings) may be additionally formed between the first gate dielectric layer 118 and the first gate layer 120, but it is not limited thereto. Accordingly, the formation of the first transistor 110 is completed, and the first transistor 110 can be used as a GAA transistor.

Furthermore, in a subsequent process, the mask layer 246 can be intermediately removed, and after the mask layer 246 is completely removed, the second gate dielectric layer 138 (including a dielectric material with a high dielectric constant, for example) and the second gate layer 140 (including a metal material with a low resistance, such as aluminum, tungsten or titanium, etc.) filling the second gate trench 242 are sequentially formed in the second region 106. In one embodiment, a work function metal layer (not shown in the drawings) and at least one barrier layer (not shown in the drawings) can also be additionally formed between the second gate dielectric layer 138 and the second gate layer 140, but it is not limited thereto. Thus, the second gate dielectric layer 138 and the second gate layer 140 together form a second gate structure 136 disposed above the superlattice channel layers 134. Accordingly, the formation of the second transistor 130 is completed, and the second transistor 130 can be used as a FinFET.

According to the method described in the above embodiments, a GAA transistor and a FinFET are integrated by forming the first gate structure and the second gate structure on the channel layers and the superlattice channel layers, respectively. Under this configuration, the GAA transistor and the FinFET can be formed simultaneously in the same process. Therefore, the method according to the present invention is advantageously in fabricating a semiconductor device including both N-type GAA transistor and P-type FinFET with small configuration area and high electron mobility. The resulting semiconductor device can thus be applied to specific devices (such as inverters, static random access memories, etc.) and achieve excellent operational performance and device efficacy.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a first transistor disposed on the substrate, and comprising:
two first source/drain structures;
a plurality of channel layers separately disposed on the substrate and between the two first source/drain structures; and
a first gate structure surrounding the channel layers; and
a second transistor disposed on the substrate, and comprising:
two second source/drain structures;
a superlattice channel layer disposed on the substrate and between the two second source/drain structures, wherein the superlattice channel layer comprises a plurality of first superlattice layers and a plurality of second superlattice layers, which are alternately stacked on the substrate; and
a second gate structure disposed above the superlattice channel layer.

2. The semiconductor device according to claim 1, wherein a topmost surface of the channel layers and a topmost surface of the superlattice channel layer are located on a same plane.

3. The semiconductor device according to claim 1, wherein a thickness of each of the first superlattice layers is equal to a thickness of each of the second superlattice layers.

4. The semiconductor device according to claim 1, wherein a thickness of each of the first superlattice layers is greater than a thickness of each of the second superlattice layers.

5. The semiconductor device according to claim 4, wherein each of the second superlattice layers and each of the channel layers comprises identical material.

6. The semiconductor device according to claim 1, wherein the first transistor comprises an N-type transistor, and the second transistor comprises a P-type transistor.

7. The semiconductor device according to claim 6, wherein the semiconductor device comprises an inverter device, and the second transistor is configured as a pull-up transistor.

8. The semiconductor device according to claim 1, wherein the first gate structure further comprises a first gate layer and a first gate dielectric layer disposed between the first gate layer and the channel layers, and the first transistor further comprises a first top spacer surrounding an upper-half portion of the first gate structure and a first bottom spacer surrounding a lower-half portion of the first gate structure.

9. The semiconductor device according to claim 1, wherein the second gate structure further comprises a second gate layer and a second gate dielectric layer disposed between the second gate layer and the superlattice channel layer, and the second transistor further comprises a second spacer surrounding the second gate structure.

10. A method of fabricating a semiconductor device, comprising:
providing a substrate;
forming a first transistor on the substrate, the first transistor comprising:
two first source/drain structures;
a plurality of channel layers separately formed on the substrate and between the two first source/drain structures; and
a first gate structure surrounding the channel layers; and
forming a second transistor on the substrate, the second transistor comprising:
two second source/drain structures;
a superlattice channel layer formed on the substrate and between the two second source/drain structures, wherein the superlattice channel layer comprises a plurality of first superlattice layers and a plurality of second superlattice layers, which are alternately stacked on the substrate; and
a second gate structure formed above the superlattice channel layer.

11. The method of fabricating a semiconductor device according to claim 10, wherein formation of the first transistor and the second transistor comprises:
forming an alternate stack of a plurality of first superlattice material layers and a plurality of second superlattice material layers on the substrate in both a first region and a second region;
forming the two first source/drain structures in the first region;
forming the two second source/drain structures in the second region;
completely removing the first superlattice material layers in the first region to form a plurality of gaps between the channel layers; and
forming the first gate structure in the first region, and forming the second gate structure in the second region.

12. The method of fabricating a semiconductor device according to claim 11, before forming the two first source/drain structures and the two second source/drain structures, further comprising:
patterning the first superlattice material layers and the second superlattice material layers in the first region and the second region to form the channel layers in the first region and superlattice channel layer in the second region;
forming a first dummy gate structure on the channel layers in the first region;
forming a second dummy gate structure on the superlattice channel layer in the second region; and
forming a second spacer around the second dummy gate structure.

13. The method of fabricating a semiconductor device according to claim 12, wherein formation of the first gate structure comprises:
completely removing the first dummy gate structure to form a first gate trench after the two first source/drain structures are formed; and
forming a first gate dielectric layer and a first gate layer in sequence in the first gate trench and the gaps.

14. The method of fabricating a semiconductor device according to claim 12, wherein formation of the second gate structure comprises:
completely removing the second dummy gate structure to form a second gate trench after the two second source/drain structures are formed; and
forming a second gate dielectric layer and a second gate layer in sequence in the second gate trench.

15. The method of fabricating a semiconductor device according to claim 12, wherein the first top spacer and the second spacer are simultaneously formed and comprise a same material.

16. The method of fabricating a semiconductor device according to claim 15, further comprising:
performing a lateral etching process to partially remove the first superlattice material layer in the first region before forming the two first source/drain structures and the two second source/drain structures; and
forming the first bottom spacer under the first top spacer.

17. The method of fabricating a semiconductor device according to claim 10, wherein the first transistor and the second transistor integrally form an inverter device, and the second transistor is configured as a pull-up transistor.

18. The method of fabricating a semiconductor device according to claim 10, wherein the first transistor and the second transistor integrally form a static random access memory device, and the second transistor is configured as an access transistor.

19. The method of fabricating a semiconductor device according to claim 10, wherein a thickness of each of the first superlattice layers is equal to a thickness of each of the second superlattice layers.

20. The method of fabricating a semiconductor device according to claim 10, wherein a thickness of each of the first superlattice layers is greater than a thickness of each of the second superlattice layers.
